(19) United States
(12) Patent Application Publication
(10) Pub. No.: US 2005/0051763 A1
(43) Pub. Date: Mar. 10, 2005

(54) Nanophase multilayer barrier and process

(75) Inventors: John David Affinito, Tucson, AZ (US); Donald Bennett Hilliard, Tucson, AZ (US)

Correspondence Address: Hilliard, Donald B., 3050 North Fontana, Tucson, AZ, 85705, US

(73) Assignee: Helicon Research, L.L.C., Tucson, AZ (US)

(21) Appl. No.: 10/934,530

(22) Filed: Sep. 4, 2004

Related U.S. Application Data
(60) Provisional application No. 60/500,903, filed on Sep. 5, 2003.

(51) Int. Cl. H01L 29/04

(52) U.S. Cl. 257/3

(57) ABSTRACT

A thin film barrier structure and process is disclosed, which is seen as particularly useful for use in devices that require protection from such common environmental species as oxygen and water. The disclosed barrier structure is of particular utility for such devices as implemented on flexible substrates, such as may be desirable for OLED-based or LCD-based devices. The disclosed barrier structure provides superior barrier properties, flexibility, as well as commercial-scale reproducibility, through the use of a novel organic/inorganic nanocomposite structure formed by infiltration of a porous inorganic layer by an organic material. The composite structure is produced by vacuum deposition techniques in the first preferred embodiment.

### BACKGROUND OF THE INVENTION

1. Field of the Invention

The invention relates generally to the field of thin film environmental barriers, and in particular, to the application of such barriers to flexible substrates utilized for device applications.

2. Description of the Related Art

There are various applications in industry where a protective coating is utilized to reduce deleterious effects of the environmental constituents upon sensitive materials. For example, various electronic devices are adversely affected by moisture that degrades insulation, initiates corrosion of parts, etc. Other devices are similarly damaged by vapors within the local environment, such as acid fumes, etc. In the medical field, constituents of the environment are often found to be detrimental due to various reactions. It has been common practice in industry that, when the various items are potentially damaged by the environment, some form of coating is applied to reduce the potential interaction.

These barrier coatings frequently comprise multilayer coatings that incorporate inorganic layers. The inorganic layers are utilized for providing a permeation barrier to the unwanted environmental constituents, due to the low diffusion rate of such constituents in the typical inorganic materials (e.g., SiO₂) utilized. It has been found in the multilayer barriers of the prior art, that it is important for the layers of inorganic material to be separated by organic material to avoid crack and defect propagation in the inorganic material. This is because a crack, pinhole or other defect in an inorganic layer deposited by various methods tends to be carried into the next inorganic material layer when the next inorganic material layer is deposited directly onto the first layer of inorganic material with no intervening layer of organic material.

The multilayer barrier structures of issue are most frequently deposited by vapor deposition. However, vapor deposition of inorganic materials onto organic substrates is restricted to relatively low-temperature processes, since the temperature of the substrate fixturing cannot exceed temperatures with which the organic substrate is compatible. As a result, many inorganic materials, particularly compounds, deposited onto organic substrates at the relatively low temperatures used are characterized by a low adatom mobility. This low adatom mobility can result in a porous film structure that exists at the nanoscale; typically, less than 100 nanometer voids, which produce essentially a “spongy” film when viewed with nanometer-scale resolution, even though the film may still appear quite specular when viewed at visible wavelengths of light. Clearly, such films are not compatible as permeation barriers, since such porous structures will readily allow high permeation rates for undesirable gases or vapors. Previous multilayer barrier structures have therefore striven to minimize pores, pinholes, and other such variously identified micron/sub-micron passageways that can frequently form in practical barrier films.

As is known in the art of vapor deposition, porous films of various inorganic materials, and in particular, inorganic compound materials, may be readily obtained by means of low temperature deposition of the inorganic material under various conditions. These porous film structures may vary considerably, but will typically comprise an open columnar microstructure, wherein the columns possess a relatively high material density, and the regions in between the columns comprise open pores or low-density porous material. However, various porous microstructures may be obtained as a function of the material deposited, substrate temperature, partial and total pressures, deposition method, type of energetic particle bombardment, etc. In sputter deposition, porosity of the deposited film can be easily varied, with the degree of porosity becoming increasingly large as sputtering pressure is increased, or as distance between sputter source and substrate is increased.

Difficulties in attaining dense, non-porous compounds—oxides, nitrides, fluorides, etc—materials in a thin film form are frequently addressed through the implementation of energetic deposition techniques. Such energetic deposition techniques utilize energetic particles—including ions, neutrals, photons, electrons, etc—to attain a structural morphology, in the deposited thin film, that is representative of an effective deposition temperature above that of the substrate. Accordingly, dense, polycrystalline (ceramic) films may be obtained on relatively low-temperature substrates.

However, such energetic deposition means beget additional difficulties. Such energetic deposition means as provided by sputtering, plasma-enhanced chemical vapor deposition, ion-assisted deposition, or the like, whereby dense, low-permeability film microstructures may be obtained, also require stringent process control and highly reproducible substrate conditions. The use of various types of conventional and high-density plasma sources for activation poses additional difficulty, in that plasma characteristics are a tenuous function of the chemical and physical environment. Such preceding issues require that the energetic methods preferred for obtaining highly dense, low permeability inorganic thin films, particularly inorganic dielectric films, be utilized in highly reproducible conditions, if a reproducible film morphology is to be obtained; otherwise, yield of reproducible barrier properties in the resultant barrier structure will be diminished. On the other hand, organic materials that these dense inorganic films are deposited onto are frequently highly outgassing materials, with surface morphologies and incorporated constituents that are highly dependent upon the specific history of the material.

As a result of complications such as those previously mentioned, the desired defect-free, inorganic layers are difficult to obtain on a routine basis using the low-temperature substrate temperatures required for the desired organic-based, low-temperature substrates. Thus, the enterprise of depositing dense, low permeability dielectrics onto organic materials can be highly problematic, especially as reproducible properties are desired on increasingly large substrates. These previous difficulties in utilizing the low permeability inorganic layers of previous barrier structures are aggravated further still by the environmental conditions subsequently encountered for most device applications.

Given the low modulus of elasticity provided by many of the inorganic barrier materials of interest in barrier applications, as well as the frequent existence of grain-boundaries, slip planes, and other such material defects in even the best inorganic barrier layers, propagation of fractures within such low-permeation inorganic layers can be expected as a result of relatively little environmental stress and cycling. Even if mechanical flexibility is not required, environmental cycling due to typical humidity and temperature cycling can be expected to have a cumulative effect on defect propagation and fracture so that the barrier properties of the inorganic layer will deteriorate over time. The reliability in sustaining such dense, fracture-free inorganic layers becomes increasingly unlikely, in the case that the multilayer barrier structure is to be subsequently subjected to mechanical stresses/strains as a result of bending, stretching, or compression.

Prior art barrier layers have circumvented some of the problems associated with the processing difficulties and relative brittle nature of inorganic compound layers through the implementation of various polymer layers which incorporate oxide inclusions (ORMOCERS) so that permeation is lowered by tortuosity induced by the oxide inclusions. However, these ORMOCER layers do not possess sufficiently low permeation rates to become the primary blocking agent in multilayer barrier structures, and are, hence, typically incorporated as interleaving layers between inorganic layers of a barrier structure.

### SUMMARY OF THE INVENTION

The previously cited limitations in previous barrier structures are addressed through the introduction of a new barrier structure and process for forming the same. In accordance with the preferred embodiments of the present invention, a novel barrier structure is disclosed, wherein a porous film of an inorganic material is formed, the porous film deposited onto an organic material, activation means provided wherein the permeable film acquires a highly activated surface condition, a wetting monomer provided for wetting the porous film, the activated surface condition sufficient to promote filling of the porous film by the wetting monomer, and a curing means provided for curing the monomer to produce a polymer, so that the porous film is transformed into a low-permeability film. This latter low-permeability film is disclosed in the present invention as an infiltrated porous barrier material (IPBM).

In its first preferred embodiment, the invention includes a vapor deposited inorganic compound, typically a transparent oxide for such optical devices as OLED and LCD displays, wherein the compound is deposited onto a moving flexible polymer sheet, as is commonly practiced in web coating. The compound is deposited so that a degree of porosity is incorporated in the resultant deposited material. An activation source is preferably used during the deposition so that the deposited inorganic acquires a high degree of surface energy on its internal surfaces. The high surface energy present within the internal surfaces of the porous inorganic material is utilized to induce infiltration of a subsequently deposited monomer, so that the porous inorganic is infiltrated by the monomer. A subsequent curing treatment provides polymerization of the monomer within the infiltrated porous inorganic, so that a novel barrier material results, comprising a polymer-infiltrated porous inorganic film.

Whereas previous vapor deposited multilayer barrier structures have relied upon use of solid inorganic layers, or in some cases, hybrid polymer films with inorganic inclusions for obtaining suitably low permeation rates, the present invention, in its first preferred embodiment, utilizes vapor deposited inorganic compounds in a thin film form that would normally be unacceptably porous and permeable for use in barrier applications. In its first preferred embodiment, the infiltrated porous barrier material (IPBM) comprises an porous inorganic layer deposited on a flexible substrate, the porous inorganic material infiltrated with a monomer that is cured to form a polymer-infiltrated porous barrier material over the flexible substrate. The porous inorganic material may contain amorphous or crystalline phases, or mixtures thereof. In its first preferred embodiment, the porous inorganic layer comprises a compound material. In an alternative embodiment, the inorganic porous material may comprise a non-reacted material, such as a pure metal, a semiconductor, a semimetal, or solid solutions thereof. While the infiltrated organic material may comprise any organic material that may be infiltrated into the porous inorganic layer, it is preferably a polymer material formed by the curing of a monomer.

Another key advantage of the present invention, over the solid continuous inorganic layers of prior art barrier structures, is the much higher toughness and fracture-resistance provided by the polymer infiltrated porous material, since the infiltrated polymer provides both greater flexibility to the IPBM, as well as greater resistance to fracture propagation. Accordingly, the presently disclosed barrier is seen as particularly well-suited to applications using flexible substrates.

Another advantage of the presently disclosed barrier structure is the relatively robust and inexpensive processing required for its fabrication, relative to the highly controlled processing required for achieving the substantially continuous inorganic layers of previous multilayer barriers. The novel infiltrated porous barrier material (IPBM) of the present invention can thus be substituted for the relatively rigid and dense inorganic barrier layers utilized in any multilayer barrier structure of the prior art.

In one preferred embodiment of the disclosed barrier, the function of the barrier is to prevent environmental constituents including but not limited to water, oxygen and combinations thereof from reaching the OLED device. Accordingly the invention is a method for preventing water or oxygen from a source thereof reaching an electronic device. Due to the novel properties of the disclosed IPBM layer—in particular, the characteristics of both an effective permeation barrier combined with those of a relatively flexible material—it may be found advantageous to substitute the disclosed IPBM for either the organic or inorganic layers used for barrier properties in prior art OLED structures. Alternatively, the IPBM of the present disclosure may be interleaved with the existing barrier materials of the prior art OLED devices. There are numerous OLED devices that incorporate a barrier structure in the prior art, many of which teach barrier multilayers comprising distinct layers of transparent inorganic materials alternating with distinct layers of transparent polymers. Such OLED devices are disclosed in numerous references, including U.S. Pat. No. 6,503,634, U.S. Pat. No. 6,503,634, U.S. Pat. No. 05,686,360, U.S. Pat. No. 05,757,126, U.S. Pat. No. 05,757,126, U.S. Pat. No. 06,413,645, U.S. Pat. No. 06,413,645, U.S. Pat. No. 06,497,598, U.S. Pat. No. 06,497,598, and various referenced and referencing patents of these disclosures, as well as the following US patent applications: US200030124392, US200030124392. Accordingly, in any of these prior art OLED barrier structures, the dyad of both polymer layer and inorganic layer, the inorganic layer alone, or the polymer layer alone, may optionally be substituted by the IPBM layer of the present invention. It may also be seen that the inorganic transparent conductors (e.g, ITO, zinc oxide, magnesium oxide, etc) may be utilized to form the porous inorganic layer of the present invention. Conversely, conducting polymers (e.g., polyaniline, polypyrole, etc) might be used as the infiltrated organic material.

As is common in the materials sciences, the terms “pore” and “porous” will, in the present disclosure, refer to the characteristic of a material to posses microscopic voids, wherein the voids possess substantially lower material density than surrounding material. Thus, porosity does not specify a particular characteristic shape of the voids, only the degree to which fillable voids exist. Accordingly, the degree of porosity is ascertained in the prior art, and in the present disclosure, by the amount of a particular substance that may be consumed in filling the pores of a unit volume of the porous material. Also, the terms “nanophase” and “nanoporous” are used in the present disclosure to describe material properties that are utilized in the preferred embodiments. Whereas the present invention is not limited to such dimensional restraints, the terms “nanophase”, “nanoporous”, and nanoscale, will refer, as in previous work in the nanomaterials field, to materials wherein the heterogeneity in question has a spatial dimension on the order of less than a micron. The term “compound” or “compounds” refers herein, as it does in the prior art of materials sciences and engineering, to a material formed by the reaction of at least two elements. Accordingly, all oxides, nitrides, fluorides, carbides, borides, phosphates, sulfates, silicates, selenides, lanthanides, cuprates, cobaltites, magnatites, tellurides, arsenates, various intermetallic compounds, and any other such reacted material, is included in this definition.

Other objects and advantages are as follows:

One object of the invention is to provide a multilayer barrier structure that may be economically fabricated on a commercial scale.

Yet, another object of the invention is to provide an IPBM layer that possesses desired properties of both glass and polymer layers.

Another object of the invention is to provide an inorganic-containing layer that may be contacted by equipment.

Yet, another object of the invention is to provide an IPBM layer, wherein the porous inorganic possesses a barrier defect density greater than 1,000,000/cm².

Another object of the invention is to provide a barrier structure of all-composite layers-no polymer layers.

Another object of the invention is to provide a smoothing process, wherein excess condensed polymer is re-volatilized as a result of not sharing inorganic-organic bonds.

Another object of the invention is to provide a multilayer barrier structure that is highly reproducible, so that high yield in industrial scale manufacturing may be maintained.

Another object of the invention is to provide a multilayer barrier structure that allows a higher degree of bending/flexibility than previous barrier designs.

Another object of the invention is to provide a multilayer barrier structure wherein an organic/inorganic composite layer provides significantly greater fracture resistance over inorganic layers of the prior art, while providing equivalent or greater barrier properties.

Another object of the invention is to provide a multilayer barrier structure that allows repeated flexing of the structure without degradation of barrier properties.

Another object of the invention is to provide an OLED device that is fabricated without the use of processing steps that are potentially damaging to the device.

Another object of the invention is to provide a multilayer barrier structure wherein permeation is limited by eliminating surface states residing within an inorganic layer of the barrier structure.

Another object of the invention is to provide a multilayer barrier structure that incorporates an IPBM.

Another object of the invention is to provide a multilayer barrier structure that incorporates a plurality of IPBM's without requiring a separate interleaving layer.

Another object of the invention is to provide a multilayer barrier structure wherein an IPBM layer is incorporated, the IPBM layer possessing a graded composition.

Another object of the invention is to provide a multilayer barrier structure that provides improved adhesion between its various component layers.

Another object of the invention is to provide a process and method for producing a multilayer barrier structure, wherein a monomer permeates a highly defective inorganic layer to produce a composite layer.

Another object of the invention is to provide a process and method for producing a multilayer barrier structure without energetic ions.

Another object of the invention is to provide a process and method for producing a multilayer barrier structure on a cooled substrate.

Another object of the invention is to provide a process and method for producing a multilayer barrier structure that allows the formation of highly defective inorganic layers.

Another object of the invention is to provide a process and method wherein surface activation induces the filling of pores.

Another object of the invention is to provide a process and method wherein substantially identical layers may be sequentially deposited for fabricating a barrier structure.

Another object of the invention is to provide a process and method for producing a multilayer barrier structure, wherein inorganic/organic composite layers are formed in a highly reproducible vapor deposition process.

Another object of the invention is to provide a multilayer barrier structure wherein surface mobility of unwanted species is substantially reduced.

Another object of the invention is to provide a process and method for producing a multilayer barrier structure, wherein a highly defective inorganic layer is impregnated with monomer through a high degree of surface activation.

Another object of the invention is to provide a process and method for producing a multilayer barrier structure, wherein a highly defective inorganic layer is impregnated with monomer so that a heterogeneous organic/inorganic composite structure is produced, wherein the composite structure possesses feature sizes of several to hundreds angstroms.

Another object of the invention is to produce a composite layer with permeation rates comparable to a solid inorganic layer, while providing greater flexibility through the fracture resistance of organic bonding.

Another object of the invention is to provide an environmental barrier structure that can withstand repeated thermal cycling.

Another object of the invention is to provide an environmental barrier structure that can withstand repeated humidity cycling.

The subject matter of the present invention is particularly pointed out and distinctly claimed in the concluding portion of this specification. However, both the organization and method of operation, together with further advantages and objects thereof, may best be understood by reference to the following description taken in connection with accompanying drawings wherein like reference characters refer to like elements.

### BRIEF DESCRIPTION OF THE DRAWINGS

FIG. 1 is a cross-section view of a typical prior art barrier structure, wherein inorganic layers are interleaved with organic layers.

FIG. 2 is a schematic representation of permeation mechanisms of prior art multilayer barriers.

FIG. 3(a) is a perspective view of a typical porous metal oxide thin film that is deposited at room temperature. The perspective view of is provided by Atomic Force Microscopy. microscopically discontinuous structure.

FIG. 3(b) is a perspective view of a metal oxide thin film that is deposited with an energetic deposition method. The perspective view of is provided by Atomic Force Microscopy.

FIG. 4(a) is a perspective view wherein a rendering of an anisotropic porous inorganic layer is shown for pointing out embodiments of the invention.

FIG. 4(b) is a second perspective view wherein a rendering of an anisotropic porous inorganic layer is shown for pointing out embodiments of the invention.

FIG. 5(a) is a microscopic cross-sectional view of a porous inorganic layer of the present invention.

FIG. 5(b) is a microscopic cross-sectional view of a porous inorganic layer of the present invention, wherein the porous region is wetted by a cured monomer.

FIG. 5(c) is a microscopic cross-sectional view of a porous inorganic layer of the present invention, wherein the porous region is partially wetted by a cured monomer.

FIG. 6 is a sectional view of an anisotropic porous inorganic layer.

FIG. 7 is a cross-sectional view of an IPBM in one preferred embodiment.

FIG. 8 is a sectional view of an IPBM in an alternative preferred embodiment.

FIG. 9 is a sectional view of an IPBM in another preferred embodiment.

FIG. 10 is a sectional view of a porous inorganic layer in another preferred embodiment, wherein the porous inorganic layer is substantially isotropic.

FIG. 11 is a sectional view of an IPBM in another preferred embodiment, wherein the porous inorganic layer is substantially isotropic.

FIG. 12 is a representation of assorted monomer molecules showing long and short aspects.

FIG. 13 is a cross-section of the invention incorporated into a multilayer barrier wherein the IPBM of the invention is alternated with inorganic layers.

FIG. 14 is a cross-section of the invention incorporated into a multilayer barrier wherein the IPBM of the invention is alternated with polymer layers.

FIG. 15 is a cross-section of an OLED device structure, utilizing the disclosed barrier material in one of its preferred embodiments.

FIG. 16 is a cross-section of the invention in an alternative embodiment, wherein the disclosed IPBM is utilized in a multilayer barrier structure that incorporates a first solid inorganic layer between a flexible substrate and the IPBM.

FIG. 17 is a schematic of a chamber used in for the process of forming an IPBM.

### DESCRIPTION OF THE PREFERRED EMBODIMENTS

List of Elements

substrate (1)
flexible substrate (1)
polymer layer (2)
substantially continuous inorganic layer (3)
anisotropic porous inorganic layer (4)
isotropic porous inorganic layer (4)
columns (5)
tortuous path (6)
infiltrated column (7)
low density porous region (8)
infiltrated polymer (9)
infiltrated porous barrier material (IPBM) (10)
polymer void (11)
undesired particles (19)
pinhole (13)
inorganic vapor source (21)
Device structure (25)
Transparent conductor (27)
drum(31)
supply reel(32)
take-up reel (33)
activation source (34)
cure source (35)
chamber structure (36)
plasma pretreat source (37)
monomer source (38)
gas source (39)

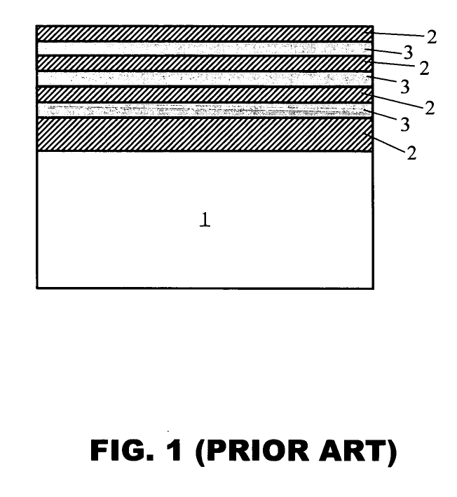

The following description and FIGS. 1-17 of the drawings depict various embodiments of the present invention. The embodiments set forth herein are provided to convey the scope of the invention to those skilled in the art. While the invention will be described in conjunction with the preferred embodiments, various alternative embodiments to the structures and methods illustrated herein may be employed without departing from the principles of the invention described herein.

Many previous efforts to implement an effective and viable multilayer thin film barrier structure have found that an inorganic layer is often required for attaining suitably low permeation rates. This use of inorganic layers is found necessary due to the finding that all organic layers, explored thus far, provide diffusion rates, to various gases and vapors of interest, that are orders of magnitude too high. Accordingly, an inorganic barrier layer must be incorporated into such multilayer barrier structures, the inorganic barrier layer, by necessity, providing nearly all of the needed barrier properties. A typical example of such a multilayer barrier structure, in FIG. 1, incorporates at least one inorganic layer (3), which is typically formed between an underlying polymer (organic) layer (2) and a second overlying polymer layer (2). The inorganic layer (e.g., SiO₂) will ideally provide the lowest possible permeation rate to undesirable constituents; and, furthermore, this low permeation rate is often projected as being potentially as low, in theory, as that of the corresponding bulk inorganic material (e.g. fused silica).

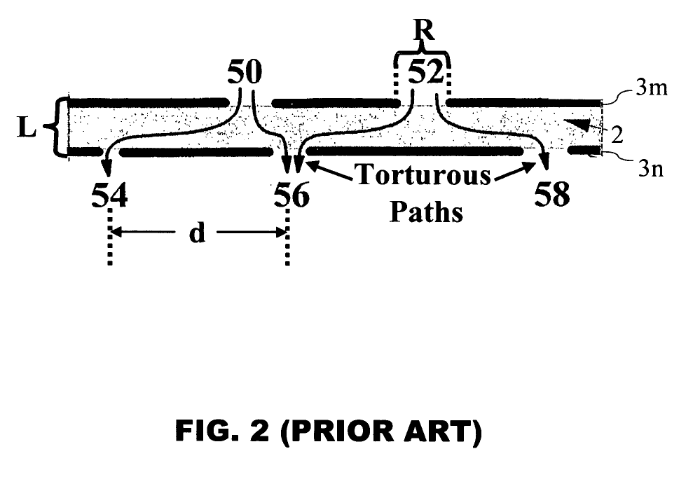

The multilayer barriers of the prior art are found to provide good barrier properties by virtue of a synergistic effect provided by the alternating layers of organic and inorganic layers. This synergistic effect has been determined to comprise a tortuosity in permeation of undesirable constituents (19) between pinholes of different inorganic layers, as set forth in FIG. 2. Pinholes (50, 52) residing in one substantially continuous inorganic layer (3m) of a multilayer barrier may allow gas flow into the underlying polymer layer (2). However, in FIG. 2, it may be seen that, due to offset of pinholes (54, 56, 58) in the subsequent substantially continuous inorganic layer (3n), a tortuosity is introduced that impedes permeation of the unwanted gas. Thus, the tortuosity is increased as the path width, L, between the pinholes, as defined by the thickness of polymer layer (2), becomes smaller. Alternatively, tortuosity is also increased as the distance between the pinholes, d, becomes larger, or the pinhole width, R, becomes smaller.

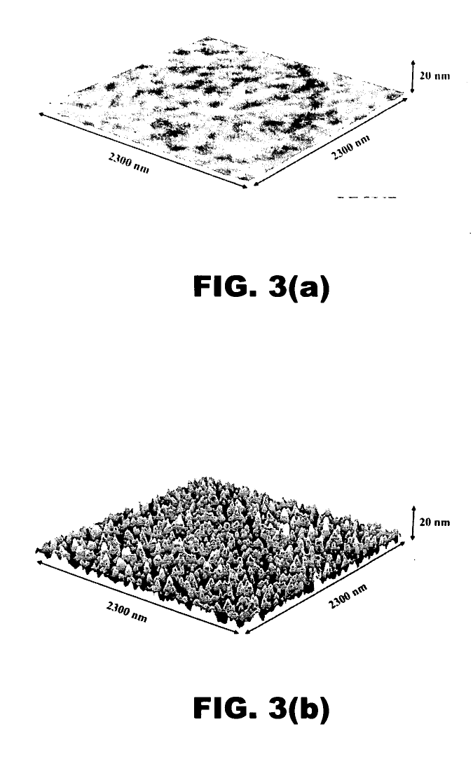

Various characterization methods relied upon for determining thin film morphologies, such as Atomic Force Microscopy, determine that compound thin film materials may be deposited in various forms. The microstructure and surface morphology of a vapor-deposited thin film of a particular compound (e.g. SiO₂), deposited on a substrate at nominally room temperature, for example, may be found to vary drastically as a function of such deposition parameters as total pressure, partial pressure, the assistance of energetic particles, deposition rate, distance, material deposited, etc. For barrier applications utilizing inorganic layers, prior art barrier structures have required that the inorganic layer be deposited in a planar, substantially continuous form, as in FIG. 3(a), so that the inorganic layer may supply barrier properties to unwanted permeation of such undesirable constituents as water or other oxygen-bearing molecules. For such prior art barrier layers, unwanted permeation is blocked due to the low diffusion rate of such unwanted constituents in the inorganic layer, so that permeation is limited to occasional pin-holes in the substantially continuous inorganic layer. Because the prior art inorganic barrier layer of FIG. 3(a) is the layer that physically blocks permeation, its performance as a barrier is determined by the degree to which it is continuous and free of holes.

An example of an inorganic thin film layer that is contradictory to the requirements of a good barrier layer is shown in FIG. 3(b). In room temperature deposition of such relatively high bond-energy materials as oxides and other reacted compounds, island growth initiated in the initial stages of vapor deposition will often result in a shadowing mechanism that begets formation of separate column-like structures from the initial onset of film growth. The space between the columns are then of relatively low density or open space, while the columns will be of relatively high density, though still potentially of significant porosity. Thus, the deposited structure represented in FIG. 3(b) will frequently be a substantially discontinuous collection of columnar structures, in that each columnar structure provides a material-dependent regularity of gas pathways surrounding each peak of the columnar structure. Such gaseous pathways intersect both top and bottom terminations of the deposited structure, with regularity typically on the order of that of the peak density. Accordingly, this substantially discontinuous structure, FIG. 3(b), is ineffective as a barrier layer,

Good barrier properties are achieved, in prior art multilayer barrier structures, with good barrier inorganic layers; i.e., the inorganic layer must not provide a high permeation rate for undesirable gaseous/vaporous particles, such as water and oxygen. As such, inorganic barrier layers that are represented by the structure of FIG. 3(a) are normally required.

Clearly, the structure of FIG. 3(b) is usually avoided for purposes of providing a barrier layer, since such a film structure, as described in FIG. 3(b), cannot possibly provide effective barrier properties in preventing water or oxygen from crossing such a barrier structure. For these reasons, the prior art layer structure of FIG. 3(a) is required in prior art multilayer barrier structures, with the necessary exclusion of the discontinuous structure of FIG. 3(b).

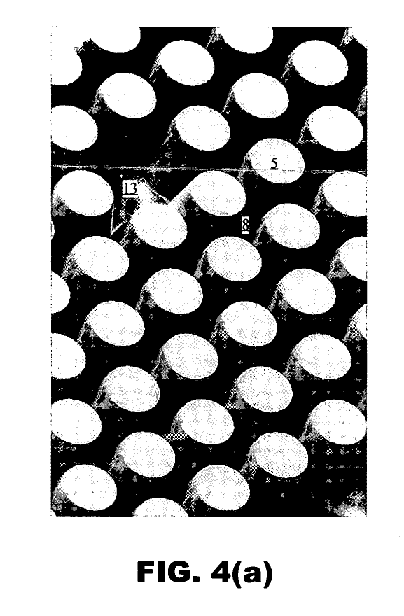

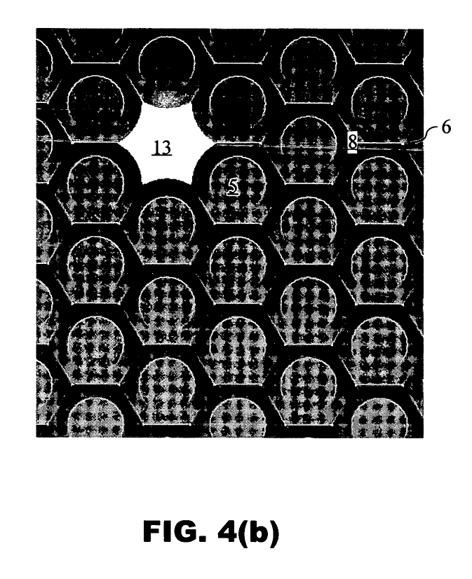

A graphic perspective representation of the porous inorganic material of the first preferred embodiment of the invention, in FIG. 4(a) and FIG. 4(b), more clearly points out salient features of such typical open columnar structures, wherein the relatively low-porosity columns (5) are shown to be separated by low density regions (8). Occasional pinholes (13) are known to cccur, though they typically exist with a spacing on the order of a micron in any acceptable inorganic barrier layer. In contrast, the columnar spacings will typically exist with a regularity on the order of a few to hundreds of nanometers, so that the inter-column regions (8) form a dense array of nanoscale porosity that provides an equally dense array of tortuous paths to the underlying substrates. The low density regions (8) residing in the interstices of the higher density columns (5) will typically provide the most direct tortuous paths (6) to the underlying material, as indicated in the areal view of FIG. 4(b). As may be seen by the structure of the porous inorganic material in FIG. 4, the porous inorganic material may possess a graded porosity that changes significantly through the thickness of the film. Furthermore, the porosity of the porous inorganic may possess directionality, as is evident in the directionality of the columns (5). Accordingly, the porous inorganic may be a substantially anisotroic inorganic material.

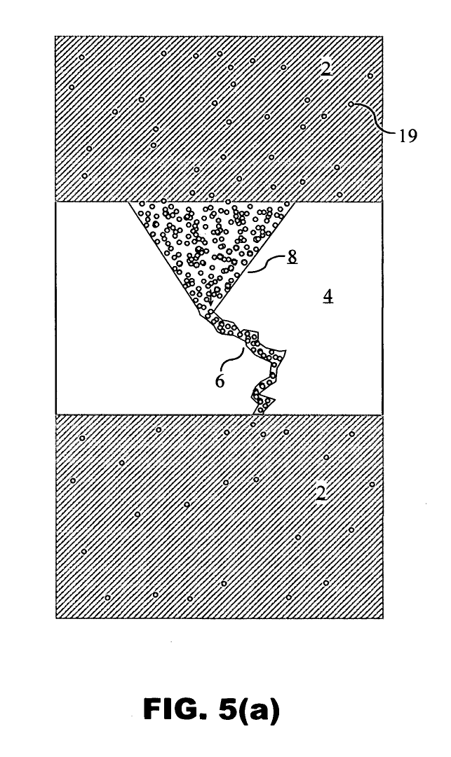

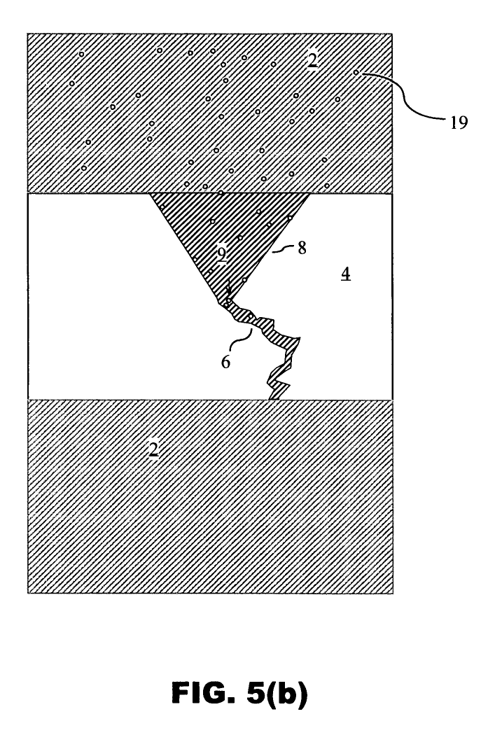

To clearly set forth novel aspects of the present invention, a cross-section of a single porous volume, in FIG. 5(a), demonstrates that, due to the open nature of the low-density porous region (8), the density allowed for an unwanted gas/vapor molecule, such as oxygen or water, may be very much higher that that allowed in the solid materials of the adjacent multilayer barrier structure. This high density of unwanted constituents may be understood in the contest of both the high solubility and high condensibility of gases/vapors in the porous region. Accordingly, a much lower cross-section of porous region may provide an equivalent flux of the unwanted constituent.

In accordance with the preferred embodiments, if the porous region (8), in FIG. 5(b), is wetted with a wetting monomer, such that subsequent curing of the monomer results in the porous region being filled with a polymer material, both solubility and condensibility of the unwanted constituents may be seen to drop significantly, due to the corresponding drop in solubility and surface energy introduced by the infiltrated polymer (9).

While it is preferred in many circumstances to maximize the degree of filling of the porous regions (8) by the infiltrated polymer (9), there may conceivably be certain circumstances in which it is preferable to have only partially filled porous regions in the porous inorganic, as in FIG. 5(c), so that various polymer voids (11) may be incorporated in the infiltrated polymer. However, the corresponding drop in permeability, due to such partial infiltration, can still be quite adequate for many barrier applications.

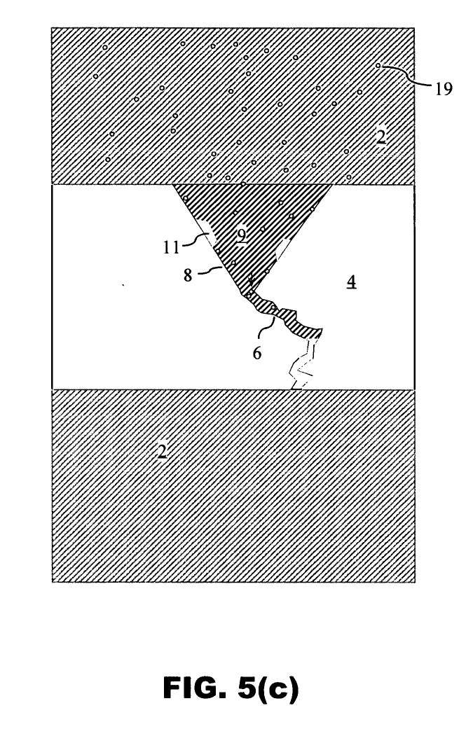

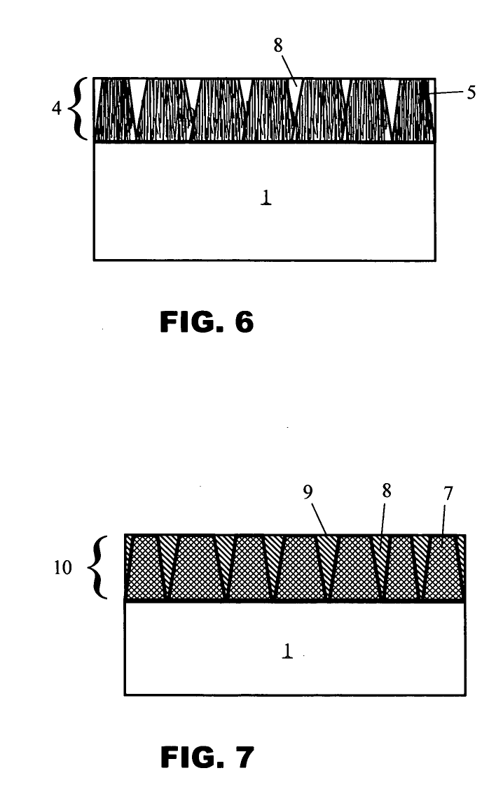

A cross-sectional representation of a substantially anisotropic porous inorganic layer (4) of FIGS. 3-4 is shown in FIG. 6, wherein the porous inorganic layer is shown at a less magnified scale than in FIG. 5. In FIG. 6, the porous inorganic layer (4) is deposited onto a generic substrate (1). In addition to uncoated substrate materials, the substrate may be any underlying material of prior art barrier structures, including but not limited to the various polymer, glasses, ceramics, polycerams, composites, etc, as well as any additional thin film structure taught in the prior art of barrier structures and devices combined therewith.

After infiltration of the porous inorganic layer, a resultant IPBM structure, in FIG. 7, results. In this first preferred embodiment, the porous inorganic layer is infiltrated with a monomer, so that the porous structure is effectively filled with the monomer, the monomer being driven into the nanoporous regions of the porous inorganic by the high surface energy present on the inorganic layer's internal surfaces. Thus, a method and structure are disclosed by which the porous, permeable layer set forth in FIG. 3(b) and FIG. 4(a&b) is transformed into an effective barrier layer that may be utilized as a substitute for the substantially continuous inorganic layer of FIG. 3(a) utilized in prior art multilayer barriers. The present invention introduces an approach wherein a substantially discontinuous layer is first deposited to provide the nanoporous structure of FIG. 3(b). This nanoporous material is preferrably treated with an activation process so that surface energy within the nanoporous material becomes unusually high, relative to that achievable in normal atmospheric processes.

It is discovered that permeation rates of inorganic thin films of the structure in FIG. 3(b) can be thus transformed to provide permeation rates as low or lower than those described for the prior art barrier layer structure of FIG. 1. Such low permeation properties are achieved with such defect-ridden layers by incorporating this defective layer structure into a unique composite structure providing several key advantages over the inorganic barrier layers of the prior art.

In a first preferred embodiment of the invention, in FIG. 7, the disclosed barrier structure is provided in the form of a loose columnar structure of inorganic, the columnar structure being consequently infiltrated with a cured monomer to produce a highly anisotropic IPBM (10).

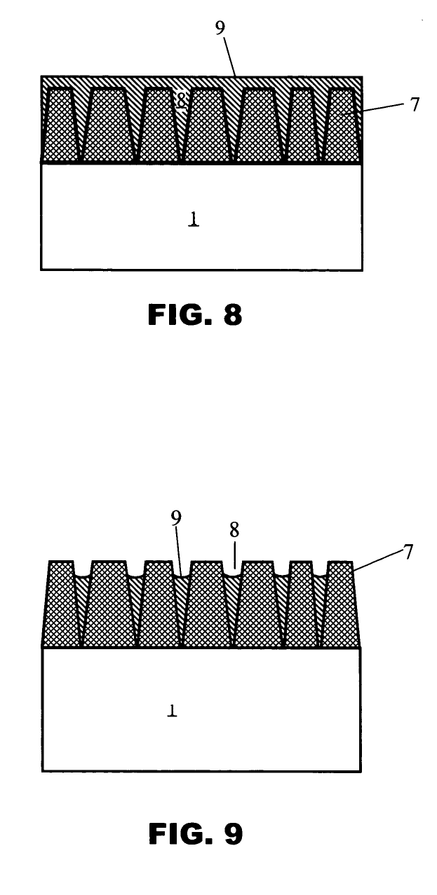

It should be noted that the porous inorganic layer may be saturated, as in FIG. 7, over saturated, as in FIG. 8, or undersaturated, as in FIG. 9, without departing from the principles and advantages of the invention set forth herein. That is, the amount of cured monomer residing in the resultant IPBM may correspond to equal to, more than, or less than, the porosity of the porous inorganic layer, while still providing the novel barrier structure and mechanism of the invention.

Because of the unique structure of the anisotropic porous inorganic layer, as embodied in FIGS. 3-9, the resultant IPBM layer provides an advantageous combination of low permeability and flexibility, due to the resultant network of infiltrated polymer. The higher elastic modulus of the polymer, relative to the brittle inorganic compounds typically used for the porous inorganic layer—or for the inorganic barrier layers of prior art barrier structures—provides a flexibility in the IPBM, as well as a resistance to fracture, that is not possible with normal ceramic or glassy barrier materials. Such flexibility without fracture may be seen to improve as adhesion between the infiltrated polymer (9) and the internal surfaces of the porous inorganic material is increased due to the high surface energy of the inorganic material prior to infiltration.

As suggested earlier in the present disclosure, the porous inorganic layer (4) need not possess a specific morphology to provide a suitable material for the subsequent infiltration by a monomer. In fact, the porous inorganic layer may possess any of a variety of nanoporous and microporous shapes specified in the prior art of porous media, except that such microporous and nanoporous morphologies should provide sufficient surface energy for wetting and infiltration by the selected monomer, so that an IPBM layer is formed.

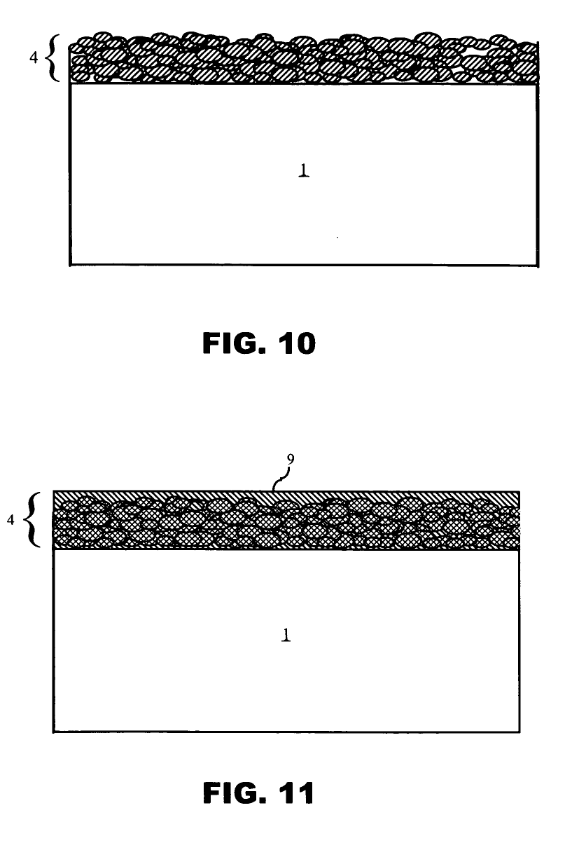

Porous inorganic film morphologies may thus provide any of a number of void shapes—spherical, cylindrical, polygonal, slits, tortuous voids, fractal-type spaces, etc—without departing from the principles or advantages of the present invention, provided that the particular inorganic porous layer allows subsequent infiltration by the monomer. As an example of another morphology, in FIG. 10, the porous inorganic can be a material sputter deposited at sufficiently high pressures (typically >15 mTorr) to result in a deposited structure comprising a substantially isotropic assembly of roughly spherical particles, an isotropic porous inorganic layer (4), such as may be witnessed in the deposition of various materials such as platinum black, carbon black, and various compounds, which provides essentially the functionality of the previously disclosed anisotropic porous inorganic layer. Deposited under sufficiently activating conditions, the surface area resulting from such an assembly will, in turn, be sufficient to promote infiltration of this porous structure by a subsequently deposited wetting monomer, so that an IPBM is formed, in FIG. 11. It is possible that the porous inorganic layer of FIG. 10 may, instead, be formed through deposition of nanoparticles or nanopowders that are manufactured via means known in the art of nanoparticles, and the nanoparticles deposited onto a substrate by such proven methods as plasma spray, thermal spray, etc.

As pointed out in the embodiments of FIGS. 3-11, the porous inorganic layer (4) and the resulting IPBM (10) may possess a wide range of morphologies, graded structures, anisotropic structures, and empty pores in various upper or lower regions of the porous layer, without departing from the spirit or scope of the invention. For example, as previously discussed, the range of porosity may vary greatly while still providing effectively low diffusion rates/permeability to undesired particles. In fact, the approach of the present invention may be applied even to even quite dense (e.g., >99% density) inorganic materials for obtaining the novel structures and advantages disclosed herein, since very little polymer material is actually required to greatly reduce the permeability of tortuous paths within the inorganic matrix of such relatively dense materials. Of equal importance, very little polymer is required to greatly increase fracture resistance of the inorganic material, if the infiltrated polymer is concentrated at the point of fracture propagation, such as the pinhole (13) in FIG. 4(b).

Also, the porous inorganic layers of the present invention can represent abnormally large amounts of surface area, such as when the inorganic layers approach structures similar to those typical of the zeolites and other such high surface area materials; however, not all surface area within such materials need be infiltrated by the monomer to achieve an effective permeation barrier. Accordingly, it is not required that all of the pores within the porous organic layer be filled; in fact, the novel results and advantages of the present invention are obtained so long as those pores that substantially contribute to permeation are substantially filled by the monomer.

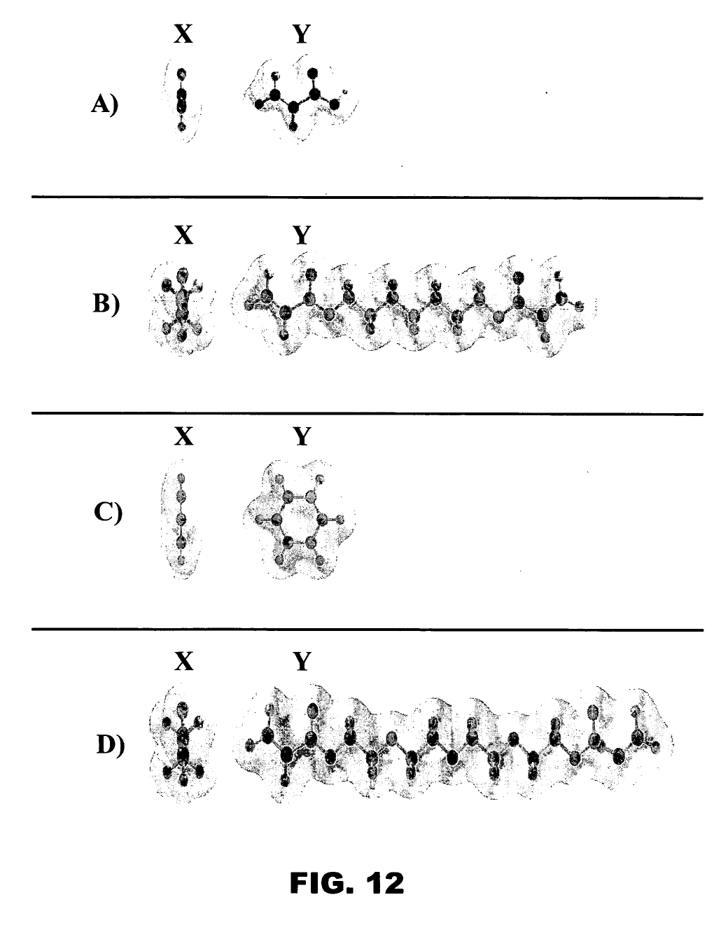

An understanding of the infiltration potential of various monomer molecules may be acquired through consideration of their physical and chemical attributes, in association with the pore sizes that are encountered in nano-porous inorganic layers. Various selected wetting molecules, in FIG. 12, can be utilized for infiltrating the pores. The free-molecule dimensions are only a first estimation of the minimum pore size that may be traversed by a particular molecule, since forces provided by the mutual forces between the molecule and surface energy of the pore will result in deformation of the molecule, so that even smaller dimensioned pores are capable of being wet by the wetting molecule.

TABLE 1

| | | Length | Width | |
|---|---|---|---|---|
| MOLECULE | | Y | X | Height |
| A) | Acrylic Acid (AA) | 6.45 Å | 4.23 Å | 1.92 Å |
| B) | Hexanediol Diacrylate (HDODA) | 20.03 Å | 4.93 Å | 3.12 Å |
| C) | Benzene | 6.22 Å | 5.54 Å | 1.92 Å |
| D) | Tetraethyleneglycol Diacrylate | 24.03 Å | 5.60 Å | 3.07 Å |
| | (TEGDA) | | | |

The width, X, and length, Y, for the wetting molecules are given in Table 1. As may be deduced from the table, the wetting molecules described are capable of infiltrating into pore sizes on the order of several angstroms. While Table 1 gives dimensions for both monomer and non-monomer molecules, it may be seen from the table that the monomers, such as HDODA and TEGDA, possess aspects that allow wetting of pores of sizes roughly equivalent to those wetted by much smaller molecules, such as benzene and acrylic acid. Accordingly, a variety of monofunctional and multifunctional acrylate and methacrylate monomers, which may be identified by reference to the Sartomer catalog, for example, may be utilized as the infiltrating monomer.

In the preferred mode of the invention, monomer vapor is condensed onto the porous inorganic layer, whereby it is then able to wick along the internal surfaces of the inorganic layer, until all, or some useful portion of, such available tortuous by-paths of permeation are filled by the monomer. A subsequent curing step, either photo-initiated techniques, plasma treatment, or an electron beam, is then introduced for polymerization of the infiltrated monomer. The particular cure method utilized will depend on the specific choice of materials and the layer thickness, amongst other variables.

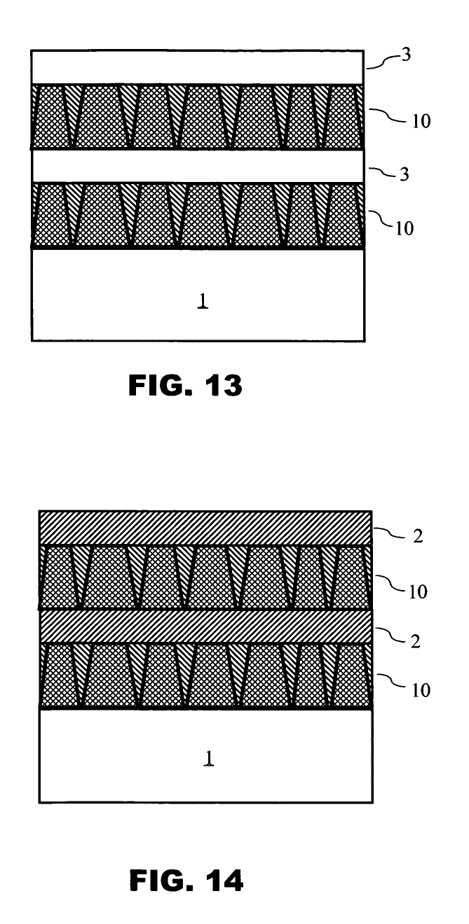

The various embodiments of the novel barrier structure, in FIGS. 5-9, may be incorporated into a variety of larger multilayer structures that provide overall barrier properties for a specific application. One such multilayer barrier structure, in FIG. 13, incorporates the novel structure and principles of FIGS. 7-11 in a larger multilayer structure. In FIG. 13, the disclosed IPBM layer (10) is interleaved with substantially continuous inorganic layers (3). As disclosed in the embodiments of FIG. 13, the IPBM layer may be substituted for the various interleaving polymer and ORMOCER layers of prior multilayer barrier structures.

Alternatively, due to its effective barrier properties, the IPBM layer (10) may also be substituted for the substantially continuous inorganic layers used variously in barrier structures of the prior art. For example, numerous IPBM layers may be interleaved with polymer layers. In FIG. 14, an IPBM (10) is deposited onto an existing substrate (1), the deposited IPBM then subsequently covered by a polymer layer (2), which is followed by another IPBM layer (10), followed by another polymer layer (2). This sequence of (10), (2), (10), (2), . . . , as in the sequence of (10), (3), (10), (3), . . . , of FIG. 13, may be continued through as many iterations as required for the application. Since the IPBM layer (10) may be substituted for either the polymer or inorganic layer of any previous multilayer barrier structure, it may accordingly be incorporated as a replacement for either the inorganic or polymer layer in any of the multilayer structures of such prior art barriers.

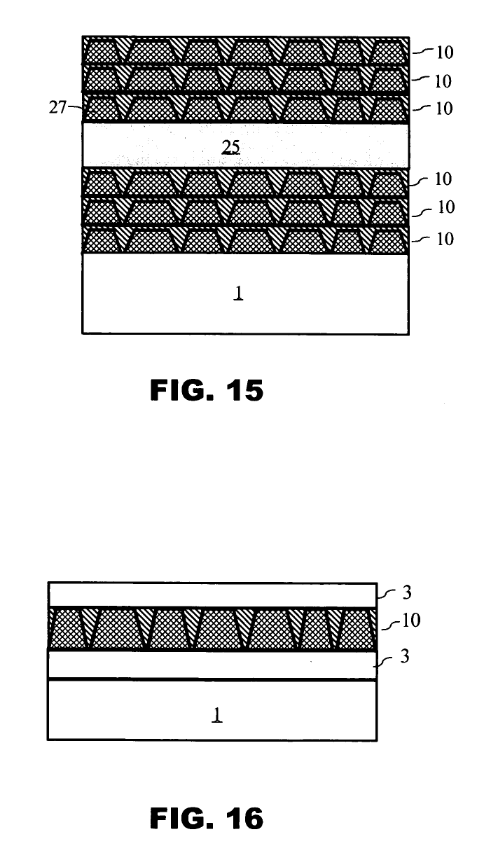

Because the novel principles of the present invention, the disclosed IPBM layer may be utilized in combinations that were previously inoperative using prior art barrier structures. For example, in FIG. 15, an effective barrier design is obtained by stacking interfacing layers of the disclosed IPBM. In this particular embodiment, the IPBM is utilized for its barrier properties in protecting an organic light-emitting diode (OLED) device structure (25). Of course, any of the barrier structures disclosed herein may be similarly used for protecting various OLED device structures. For example, a transparent electrical conductor (27) may be utilized in the porous inorganic layer. Also, while the OLED device structure (25) can incorporate any and all materials necessary for the active portion of the device, components of the OLED device might also be incorporated into the disclosed IPBM layer or multilayer structures. For example, either the porous inorganic layer (4) or the infiltrated polymer (9) may be fabricated from a material that provides electrical conductivity in the IPBM layer.

In some instances, it may be advantageous to first deposit a substantially continuous inorganic layer (3) over the substrate, as in FIG. 16, before depositing a first IPBM layer.

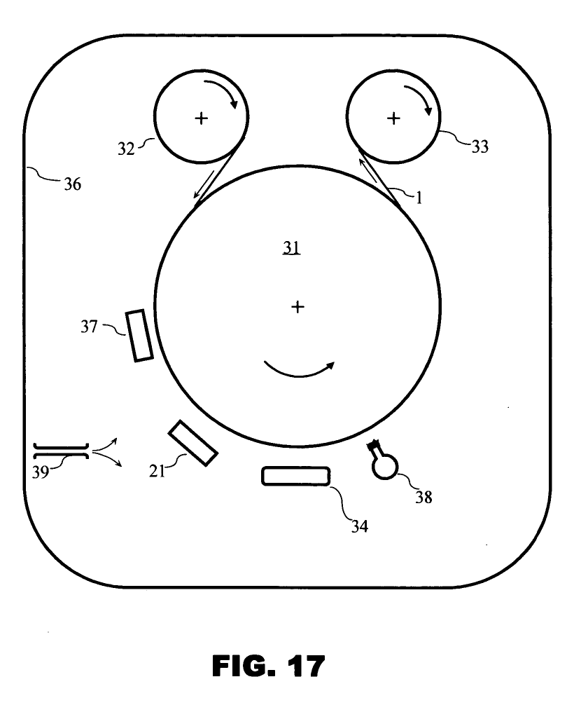

While the IPBM of the present invention may be deposited over either flexible or rigid structures, the invention is seen as most advantageously utilized as a barrier over flexible substrates. Accordingly, a web coating configuration is shown in FIG. 17, wherein the IPBM barrier of the preferred embodiments may be formed on a flexible substrate (1) compatible with various device applications. The flexible substrate may consist of any of a number of polymer films utilized in previous web coating applications, such as PET, PMMA, polyimides, polyamides, aramids, polypropylene, polysulfones, polynorborenes, Kaptons, polypyroles, polyanilenes, or any other flexible substrate material. The polymer film is typically cooled by a rotating drum (31) during deposition of the barrier structure, so that the various vapor, gas, activation, and curing sources are typically arranged around the rotating drum for treatment of the flexible substrate thereon, as is commonly practices in the art of web coating. A supply reel (32) and a take-up reel (33), are typically implemented in such web-coating equipment for the purposes of providing a continuous supply and return, respectively, for the substrate material. Other rollers, idlers, load cells, and the like that are common to web-coating equipment are eliminated in FIG. 17.

Formation of IPBM-type structures may be accomplished by a variety of means; however, in the preferred embodiments of the present invention, the IPBM is formed by vacuum vapor deposition methods and apparatus readily available in prior art manufacturing processes. Accordingly, the IPBM of the present invention may be formed utilizing a variety of prior art vapor sources for the IPBM material. The inorganic vapor source may comprise any appropriate source of the prior art, including but not limited to sputtering, evaporation, electron-beam evaporation, chemical vapor deposition (CVD), plasma-assisted CVD, etc. The monomer vapor source may similarly be any monomer vapor source of the prior art, including but not limited to flash evaporation, boat evaporation, Vacuum Monomer Technique (VMT), polymer multilayer (PML) techniques, evaporation from a permeable membrane, or any other source found effective for producing a monomer vapor. For example, the monomer vapor may be created from various permeable metal frits, as previously in the art of monomer deposition. Such methods are taught in U.S. Pat. No. 5,536,323 (Kirlin) and U.S. Pat. No. 5,711,816 (Kirlin), amongst others.

A separate activation (34) may be utilized in some cases for providing additional activation energy during or after deposition of the porous inorganic layer. In some cases, such as in certain types of unbalanced magnetron sputtering, plasma immersion, or plasma-enhanced CVD, a separate activation source (34) may not be required, as the sufficient activation is already attained by the deposition method itself. Alternatively, certain types of porous materials, such as those that provide catalytic or low work function surfaces—e.g., ZrO₂, Ta₂O₅, or various oxides and fluorides of Group IA and Group IIA metals—may provide sufficient activation even in relatively non-activating deposition processes.

For formation of the IPBM-type barrier structures, the vacuum deposition sources may be arranged variously, depending on which of the various embodiments of the invention discussed are to be formed. For formation of the IPBM structure onto a polymer, whether the polymer is the flexible substrate or an underlying cured polymer film, the porous inorganic layer (4) is first deposited by an inorganic vapor source (21), which, in the first preferred embodiment, is a linear magnetron sputter source as is commonly used for deposition of inorganics in the prior art. The magnetron may be of the unbalanced magnetron design for providing sufficient activation of the deposited inorganic during deposition. For formation of the porous inorganic layer, the magnetron source may be operated under a wide variety of operating conditions, depending on the material being deposited, the condition of the underlying substrate, the substrate temperature, partial pressures of reactive gas, total operating pressure, magnetron power, distance between the magnetron sputter source and the substrate, etc. However, in its first preferred embodiment, the IPBM of the present invention is formed by depositing a high surface energy material, such as, but not limited to, ZrO₂, SiO₂ or TiO₂, wherein the material is deposited in a total pressure of 15 mTorr, comprising 25% oxygen and 75% argon. The magnetron source is of a Type II unbalanced magnet configuration as is commonly discussed in the prior art of magnetron sputtering. As a result, a highly energetic plasma is made to contact the growing inorganic film, whereas the pressure is adequately high to promote porous film formation.

After formation of the porous inorganic layer, an additional activation source (34) may be used to promote additional activation of the porous layer' surface area if so required.

Formation of the highly activated porous inorganic layer is followed by the previously disclosed infiltration step, wherein a monomer source (38)—for example a flash evaporation or VMT monomer source—is utilized to direct a stream of monomer vapor towards the already deposited porous inorganic layer (4). The monomer vapor is made to condense onto the porous inorganic layer of the present embodiment, thereby allowing the monomer to be subjected to forces produced between the monomer and the highly activated surfaces of the porous layer. In so doing, the monomer is made to wet into and fill the porous structure, thereby providing infiltration by the monomer.

After, or, in some cases, during infiltration of the porous inorganic layer by the monomer, in FIG. 17, a curing source (35) is utilized for polymerization of the infiltrated monomer. In the case that the monomer contains photoinitiators, the curing source may be an ultraviolet (UV) light source. In the latter case of U.V. curing of the monomer, the porous inorganic layer should preferably be substantially transparent to the UV wavelengths used for the cure, such that the extinction of the UV in the IPBM layer is not so great as to prevent curing of the most deeply infiltrated monomer. Any or all of the process steps disclosed herein may involve the use of gas injection from a gas source (39), wherein various inert or reactive gases/vapors may be introduced for various modifications of the process and resultant materials. In some cases, it may be advantageous to plasma treat the substrate with a plasma treatment source (37) prior to formation of the IPBM.

Deposition means for the inorganic material may be any method used for vacuum deposition, including but not limited to chemical vapor deposition, plasma enhanced chemical vapor deposition, sputtering, electron beam evaporation, electron cyclotron resonance source-plasma enhanced chemical vapor deposition (ECR-PECVD) and combinations thereof.

Deposition of the inorganic porous structures may also be accomplished by such non-vacuum techniques as LPE, Sol-Gel, MOD, electrophoretic dep., etc. Activation in such methods may incorporate various atmospheric techniques, including but not limited to the use of surfactants, atmospheric plasmas, electron beam sources and the like.

Industrial Applicability:

The invention finds application in a variety of barrier applications; in particular, the invention is suitable for providing encapsulation in flat-panel displays, including those required for OLED and LCD related devices. For example, the novel nanophase barrier layer disclosed herein may be used to replace either organic or inorganic layers utilized in any of the various multilayer barrier structures of the prior art, thereby providing the advantages of the disclosed invention. The invention is accordingly seen as particularly suitable for providing barrier properties in flexible electronics, particularly in flexible displays.

Although the present invention has been described in detail with reference to the embodiments shown in the drawing, it is not intended that the invention be restricted to such embodiments. It will be apparent to one practiced in the art that various departures from the foregoing description and drawing may be made without departure from the scope or spirit of the invention.

1. A barrier layer, the layer comprising:
a.) a porous inorganic material deposited onto a substrate; and,
b.) an organic material infiltrated into the porous inorganic material, so that a continuous layer is formed, the layer having barrier properties.

2. The barrier layer of claim 1, wherein the layer is repeated to form a multilayer barrier structure.

3. The barrier layer of claim 1, wherein the layer has a graded composition.

4. The barrier layer of claim 1, wherein the layer may be subjected to increased bending of the structure without degradation of barrier properties.

5. The barrier layer of claim 1, wherein the layer provides improved fracture resistance over previous barriers.

6. The barrier layer of claim 1, wherein the layer may be subjected to an increased number of flexing cycles without degradation of barrier properties.

7. The barrier layer of claim 1, wherein the layer may be subjected to an increased humidity cycling without degradation of barrier properties.

8. The barrier layer of claim 1, wherein the layer may be subjected to an increased thermal cycling without degradation of barrier properties.

9. The barrier layer of claim 1, wherein the layer provides improved adhesion to a subsequent layer.

10. The barrier layer of claim 1, wherein surface mobility of a condensable species is substantially reduced.

11. The barrier layer of claim 1, wherein permeation is limited by eliminating surface states residing within the inorganic layer.

12. The barrier layer of claim 1, wherein the structure contains an amorphous phase, a crystalline phase, or mixtures thereof.

13. The barrier layer of claim 1, wherein the porous inorganic material comprises at least one compound selected from the following: oxides, nitrides, fluorides, carbides, borides, phosphates, sulfates, silicates, selenides, lanthanides, cuprates, cobaltites, magnatites, tellurides, and arsenates.

14. The barrier layer of claim 1, wherein the layer possesses feature sizes between several angstroms and hundreds of angstroms.

15. The barrier layer of claim 1, wherein the organic material is an electrically conducting polymer.

16. The barrier layer of claim 1, wherein the inorganic material is electrically conducting.

17. The barrier layer of claim 1, wherein the layer is used for manufacture of flexible displays.

18. A process for forming a barrier layer, comprising the steps:
a.) providing a substrate;
b.) depositing a porous inorganic material onto the substrate;
c.) infiltrating the porous inorganic material with a monomer; and
d.) providing curing means for polymerizing the monomer, thereby transforming the porous material and the monomer into the barrier layer, so that the layer has low-permeability characteristics.

19. The process of claim 18, further comprising a smoothing step, wherein excess condensed monomer is re-volatilized as a result of not sharing inorganic-organic bonds.

20. The process of claim 18, further comprising means to repeat the process for producing a multilayer barrier structure.

21. The process of claim 18, further comprising activation means, the activation means for increasing infiltration of the porous material.

22. The process of claim 18, further comprising means for depositing a polymer layer over the barrier layer.

23. The process of claim 18, further comprising means for cooling the substrate.

24. The process of claim 18, further comprising means for positioning the substrate.

25. The process of claim 18, wherein the substrate is a thin flexible polymer.

26. The process of claim 18, wherein the process is used in the manufacture of flexible displays.

27. An organic semiconductor device, comprising:
a.) a substrate;
b.) a semiconductor material deposited onto the substrate,
c.) a porous inorganic material deposited over the semiconductor material; and,
d.) an organic material infiltrated into the porous inorganic material so that a continuous barrier layer is formed over the semiconductor material, the layer thereby having barrier properties.

28. The organic semiconductor device of claim 27, wherein the device is an organic light-emitting diode.

29. The organic semiconductor device of claim 27, wherein the device is an organic switching device.

30. The organic semiconductor device of claim 27, wherein the barrier layer is part of a multilayer barrier.

31. The organic semiconductor device of claim 27, wherein the substrate includes a substrate layer, the substrate layer formed similarly to the barrier layer.

32. The organic semiconductor device of claim 27, wherein the substrate is a flexible material.

33. The organic semiconductor device of claim 27, wherein additional layers are formed between the semiconductor material and the barrier layer.

34. The organic semiconductor device of claim 27, wherein the substrate comprises a multitude of substrate layers that are each formed similarly to the barrier layer.

35. The organic semiconductor device of claim 27, wherein the device is a flexible display device.
